(19) United States
(12) Patent Application Publication
(10) Pub. No.: US 2011/0318143 A1
(43) Pub. Date: Dec. 29, 2011

(54) VACUUM PROCESSING APPARATUS

(75) Inventors: Ryoichi ISOMURA, Kudamatsu (JP); Susumu Tauchi, Shunan (JP); Hideaki Kondo, Kudamatsu (JP)

(73) Assignee: Hitachi High-Technologies Corporation

(21) Appl. No.: 12/854,255

(22) Filed: Aug. 11, 2010

(30) Foreign Application Priority Data
Jun. 23, 2010 (JP) 2010-142160

(51) Int. Cl. H01L 21/677

(52) U.S. Cl. 414/217.1; 257/E21.001

(57) ABSTRACT

A vacuum processing apparatus includes a first lock chamber and a second lock chamber coupled to a back face side of the atmospheric transfer chamber in parallel, a first transfer chamber coupled to a rear side of the first lock chamber, a second transfer chamber coupled, on the rear side of the first transfer chamber, a third transfer chamber coupled to the rear side of the second lock chamber, a first and a second relay chamber disposed between the first transfer chamber/the second transfer chamber and the first transfer chamber/the third transfer chamber to transfer a wafer between these chambers, and a plurality of processing chambers coupled to either the first, the second or the third transfer chamber, in addition, the number of the processing chambers coupled to the second transfer chamber is greater than that of the processing chambers coupled to either the first or the third transfer chamber, and the wafer alone processed in the processing chamber coupled to either the first or the second transfer chamber is transferred to the third robot in the second relay chamber.

### BACKGROUND OF THE INVENTION

The present invention relates to a vacuum processing apparatus in which a substrate to be processed, such as a semiconductor wafer, is processed inside a processing chamber disposed in a vacuum chamber, and in particularly to a vacuum processing apparatus coupled with the vacuum chamber and providing a transfer chamber for transferring the substrate to be processed inside the processing chamber.

In the above-mentioned apparatus, particularly, in the vacuum processing apparatus in which a substrate (hereinafter, referred to as a wafer) such as the semiconductor wafer, as a sample to be a processing target, is processed inside the processing chamber depressurized and installed in the vacuum chamber, an improvement of a processing efficiency for the wafer as a processing target has been demanded with a fine and accurate process. To this end, a multi-chamber apparatus has been developed recently, that is, a plurality of vacuum chambers are coupled to a single apparatus to be able to process the wafers in parallel, in a plurality of processing chambers. In this way, a productive efficiency per installation area of a clean room has been improved.

In the above-mentioned apparatus providing the plurality of processing chambers for processing the wafers, each of the processing chambers configures a processing unit together with a unit for supplying an electric field and magnetic field, a decompression unit such as a decompression pump for decompressing inside the processing chamber, a unit for adjusting a process gas to be supplied inside the processing chamber, etc. This processing unit includes a transfer chamber in which a gas and pressure are adjusted to be able to depressurize and a robotic arm etc. is provided, and the processing unit is coupled removably to a transfer unit for transferring the wafer inside the transfer chamber to hold it temporarily. More specifically, the processing chamber depressurized in each of the processing units is configured that a side wall of the vacuum chamber disposed inside is coupled removably to a side wall of the vacuum transfer chamber of the transfer unit to transfer the pre- or post-processed wafer inside the chamber depressurized similarly to the vacuum chamber and be able to communicate or block therethrough.

In the above-mentioned configuration, the size of entire vacuum processing apparatus is greatly affected by the size and location of the vacuum transfer chamber and vacuum processing chamber. For example, the vacuum transfer chamber is determined that its size for realizing necessary operations is subjected to affection of the number of transfer chambers or the number of processing chambers to be coupled with each other, the number of transfer robots to be disposed inside and transfer the wafer, and also of a minimum radius and the diameter size of wafer required for the operation. In contrast, the vacuum processing chamber is also affected by the diameter of wafer to be targeted for the process, a decompression efficiency inside the processing chamber for realizing a necessary pressure, and a layout of devices necessary for the wafer process. Further, the layout of vacuum transfer chamber and vacuum processing chamber is also affected by a total product amount of semiconductor devices etc. demanded by a user depending on an installed location and the number of processing chambers necessary for each of the processing apparatuses to realize the efficiency.

Further, each of the processing chambers in the vacuum processing apparatus is necessary for a maintenance such as repair, check, etc. for every predetermined operating time and every number of wafers. To this end, the layout of the devices and chambers has been demanded such that the above-mentioned maintenance is carried out effectively. Japan Unexamined Patent No. 2007-511104 has been known as related art for the vacuum processing apparatus in which the plurality of vacuum processing chambers and vacuum transfer chambers are disposed and coupled with each other.

### SUMMARY OF THE INVENTION

In the above-mentioned related art, each of the processing units or transfer units is configured that it is removably coupled with each other, therefore, the transfer unit can be exchangeable to the other processing unit in response to processing contents and condition to be demanded, or the maintenance and a performance demand, so that the configuration in response to other processes can be changed under a condition where the processing units and transfer units are installed in a building of the user. Further, the vacuum transfer chamber is configured by a polygonal shape in the plain as viewed from top, and the vacuum transfer chamber is also configured that whether the side wall of the vacuum chamber in the vacuum processing unit or the side wall of the chamber to be coupled to the vacuum transfer chamber in the other transfer unit or one another can be coupled removably to the side wall corresponding to each of the sides in the polygonal shape. In the related art, the vacuum processing apparatus in the above-mentioned configuration configures that the vacuum transfer chambers are coupled with each other (another vacuum transfer chamber may be placed in between the chambers to be coupled), therefore, the number of vacuum processing units and a degree of freedom for layout are made large, and the process and configuration can be changed for a short time period in response to a specification change requested from the user. In this way, the operating efficiency for the entire apparatus is maintained high.

However, in the above-mentioned related art, there is a problem that the following points are not considered. That is, the vacuum transfer chambers (regardless of presence or absence of the chamber in between) are coupled with each other to increase the layout of processing units and number thereof. Therefore, the layout and number etc. of the vacuum processing chamber (vacuum processing unit) and vacuum transfer chamber are not sufficiently considered of a condition where the wafer process and productive efficiency can be made optimal. In consequence, the amount of production has been lost per installation area of the vacuum processing apparatus.

For example, when the vacuum processing apparatus provides a plural type of vacuum processing units, particularly, a process of these types is applied in series to the wafer, and also when the vacuum processing unit for performing a pre-applied process and a post-applied process is coupled to the other vacuum transfer chamber, it has not been considered that the processing efficiency is lost depending on selection of the layout and the number of vacuum processing units, in the related art. In consequence, the processing capability of wafer has been lost per installation area of the vacuum processing apparatus in the related art.

An object of the invention is to provide a semiconductor manufacturing apparatus or a vacuum processing apparatus having high productivity per installation area.

The above-mentioned object is realized by a configuration below. A vacuum processing apparatus provides: an atmospheric transfer chamber disposed, on a front face side, a cassette table for mounting cassettes to store wafers and to transfer the wafers inside the cassette; a first lock chamber and a second lock chamber coupled to a back face side of the atmospheric transfer chamber in parallel to be able to adjust an pressure to a vacuum pressure inside the cassette storing the wafers; a first transfer chamber coupled to a rear side of the first lock chamber and having a first robot for transferring the wafer inside the first lock chamber set to a predetermined vacuum pressure; a second transfer chamber disposed and coupled, on the rear side of and to, the first transfer chamber and having a second robot for transferring the wafer under the vacuum; a third transfer chamber coupled to the rear side of the second lock chamber and having a third robot disposed in parallel with the first transfer chamber, for transferring the wafer inside the second lock chamber set to the vacuum; a first relay chamber and a second relay chamber coupled to and dispose between the first transfer chamber/the second transfer chamber and the first transfer chamber/the third transfer chamber so as to seal in and providing a storage unit inside such that the wafer is transferred between either the first and the second robots or between the first and the third robot; and a plurality of processing chambers coupled to either the first, the second or the third transfer chamber and for processing the wafer in the processing chamber, wherein number of the processing chambers coupled to the second transfer chamber among the plurality of processing chambers is greater than that of the processing chambers coupled to either the first or the third transfer chamber, and the wafer alone processed in the processing chamber coupled to either the first or the second transfer chamber is transferred to the third robot in the second relay chamber.

The apparatus further provides a valve disposed to seal in between the processing chambers coupled respectively to the second and the third transfer chamber, between the relay chambers, and between the first and the second lock chamber; and the valve disposed between the processing chambers coupled to the first, the second and the third the processing chambers opens exclusively between the first, the second and the third transfer chambers, and the respective processing chambers.

The number of the processing chambers coupled to the second transfer chamber is equal to or greater than two, and number of processing chambers coupled to the first and the second transfer chambers is equal to or less than one.

The wafer processed in the processing chamber coupled to either the first or the second transfer chamber is taken out to an atmospheric pressure via the second relay chamber, the third transfer chamber and the second lock chamber, when another wafer stored in the first lock chamber waits.

The wafer processed in the processing chamber coupled to either the first or the second transfer chamber is subjected to a post-process of the process inside the processing chamber coupled to the third transfer chamber.

The other objects, features and advantages of the invention will become apparent from the following description of the embodiments of the invention taken in conjunction with the accompanying drawings.

### BRIEF DESCRIPTION OF THE DRAWINGS

FIG. 1 is a top view showing a schematic configuration of an entire vacuum processing apparatus in an embodiment of the invention;

FIGS. 2A and 2B are cross-section views each showing an enlarged vacuum transfer chamber in the embodiment shown in FIG. 1; and

FIG. 3 is a top view showing a schematic configuration of an entire vacuum processing apparatus in a modified example of the invention.

### DESCRIPTION OF THE EMBODIMENT

Hereinafter, an embodiment of the vacuum processing apparatus in the invention will be described below with reference to the drawings.

### Embodiment

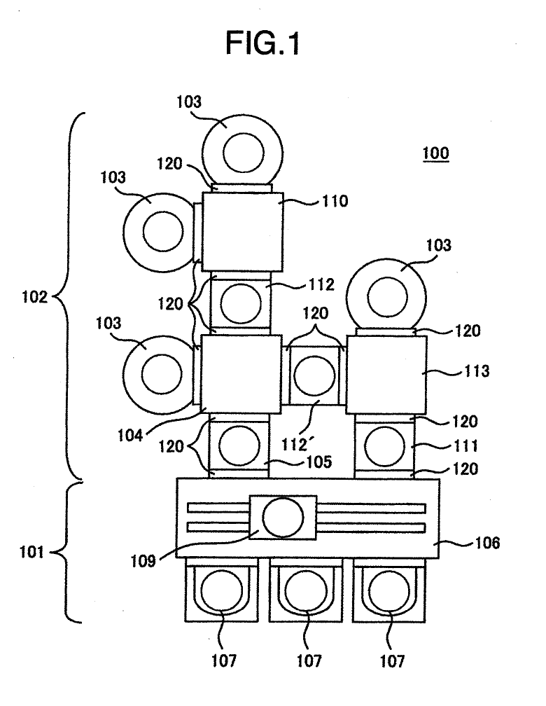

FIG. 1 is a top view for illustrating an outline of an entirely configured vacuum processing apparatus in the embodiment.

In FIG. 1, a vacuum processing apparatus 100 including vacuum processing chambers in the embodiment of the invention is largely divided into and configured by an atmospheric side block 101 and a vacuum side block 102. The atmospheric side block 101 is a portion of for transferring a substrate-shaped sample such as a semiconductor wafer etc. as a member to be processed under an atmospheric pressure, and determines a position of storing the sample, etc. The vacuum side block 102 is a portion of transferring the substrate-shaped sample including the wafer under a pressure depressurized from the atmospheric pressure to then process the sample inside a predetermined vacuum processing chamber. A portion where the pressure goes up and down between the atmospheric pressure and the vacuum pressure with the sample inside, is disposed between a place of the vacuum side block 102, in which the transfer and process are performed, and the atmospheric side block 101 to be disposed and coupled with each other.

The atmospheric side block 101 has a substantially rectangular solid-shaped chassis 106 providing an atmospheric transfer robot 109 therein. A plurality of cassette tables 107, in which the cassette storing the substrate-shaped sample such as a semiconductor wafer as a processing and cleaning target to be processed are provided, are attached on the front surface side of the chassis 106.

The vacuum side block 102 is configured by a first vacuum transfer chamber 104, a second vacuum transfer chamber 110 and a third vacuum transfer chamber 113, and further configured by at least one first lock chamber 105 and at least one second lock chamber 111 each of which exchanges the pressure between the atmospheric pressure via the block 101 and vacuum pressure with the wafer present inside. These lock chambers 105, 111 are a vacuum chamber adjustable to the above-mentioned pressure inside a space, and passages for passing the wafer through inside and transferring it and a valve 120 for opening or closing the passage to be able to seal in airtight, are disposed on the coupled places. In consequence, the atmospheric side and vacuum side are divided inside. Further, the inside space of the lock chamber provides a storage unit capable of storing and holding a plurality of wafers when a slit opens in one above the other. The valve 120 closes dividedly to keep in airtight with the wafers stored.

The first vacuum transfer chamber 104, second vacuum transfer chamber 110 and third vacuum transfer chamber 113 are a unit including the vacuum chamber having substantially rectangular shape in plain, respectively. These three units have a little bit difference between them, but substantially the same configuration. A second vacuum transfer intermediate chamber 112′ is also disposed between the side walls corresponding to opposite surfaces of the first vacuum transfer chamber 104 and third vacuum transfer chamber 113 to be coupled with each other.

A first vacuum transfer intermediate chamber 112 and the second vacuum transfer intermediate chamber 112′ are a vacuum chamber capable of depressurizing inside down to a degree of vacuum equivalent to the other vacuum transfer chambers or vacuum processing chambers, and the vacuum transfer chambers are coupled with each other to communicate with each other. The valves 120 are also disposed between the vacuum transfer chambers so that they open or close the passage used for transferring the wafer through the inside of chambers. By closing the valves 120, the vacuum transfer intermediate chamber and vacuum transfer chamber are sealed in airtight.

A storage unit, which provides spaces having an interval between for the plurality of wafers to load and hold them horizontally, is disposed inside the first and second vacuum transfer intermediate chambers 112, 112′. The storage unit provides a function as a relay chamber for storing the wafer once when the wafer is transferred between either the first and second vacuum transfer chambers 104, 110 or the first and third vacuum transfer chambers 104, 113. That is, the wafer carried in by the vacuum transfer robot 108 inside one vacuum transfer chamber and loaded on the storage unit, is taken out by the vacuum transfer robot 108 inside the other vacuum transfer chamber to then be transferred to the vacuum processing chamber 103 or lock chamber coupled to the vacuum transfer chamber.

The first vacuum transfer intermediate chamber 112, transferred the wafer to/from the second vacuum transfer chamber 110, is coupled to one surface to which the first lock chamber 105 and second vacuum transfer intermediate chamber 112 are not coupled. Further, the vacuum processing chamber 103, carried the wafer in to the internally depressurized inside to process the wafer, is coupled to the other surface. In this embodiment, the vacuum processing chamber 103 indicates an entire unit including an electric field and magnetic field generation unit configured with the vacuum chamber and a decompression unit including a vacuum pump for decompressing the space depressurized inside the chamber, and an etching process, ashing process and a process to be applied to the other semiconductor wafer are applied to the wafer inside the processing chamber. A pipe line, through which a process gas to be supplied in response to a process to be performed, is coupled between to each of the vacuum processing chambers 103.

One vacuum processing chamber 103 is coupled to the first vacuum transfer chamber 104. It is configured that three vacuum processing chambers 103 can be coupled to the second vacuum transfer chamber 110 and third vacuum transfer chamber 113, however, two or less vacuum processing chamber 103 is coupled thereto, in this embodiment.

The first vacuum transfer chamber 104 is coupled to one portion of the first vacuum transfer intermediate chamber 112, and the second vacuum transfer chamber 110 is coupled to the other portion thereof. The second vacuum transfer chamber 110 also has a substantially rectangular shape in plain or a polygonal shape similar to the rectangular shape, and side wall surfaces of the vacuum chambers configuring the two vacuum processing chambers 103 are coupled to the two side surfaces of the second vacuum transfer chamber 110. The first vacuum transfer chamber 104 is coupled to one portion of the second vacuum transfer intermediate chamber 112′ and the third vacuum transfer chamber 113 is coupled to the other portion thereof.

The third vacuum transfer chamber 113 also has the substantially rectangular solid in plain. The lock chamber 111 is coupled to one surface where the third vacuum transfer chamber 113 is opposed to the chassis 106, and the vacuum processing chamber 103 is coupled to the other surface thereof. The vacuum side block 102 is a vessel capable of maintaining a high degree of vacuum by depressurizing entirely.

The inside of first vacuum transfer chamber 104, second vacuum transfer chamber 110 and third vacuum transfer chamber 113 is set to become a transfer chamber, and the vacuum transfer robot 108, for transferring the wafer between either the first lock chamber 105 and vacuum processing chamber 103 or between the vacuum transfer intermediate chambers 112 and 112′ under the vacuum, is disposed on a central portion inside the space of first vacuum transfer chamber 104. Likewise, the vacuum transfer robot 108 is also disposed on the central portion inside the second vacuum transfer chamber 110. In this way, the wafer is transferred between the vacuum processing chamber 103 and the second vacuum transfer intermediate chamber 112.

Likewise to the above, the vacuum transfer robot 108, for transferring the wafer between either the second lock chamber 111 and the vacuum processing chamber 103 or the vacuum transfer immediate chamber 112′ under the vacuum, is disposed on the central portion inside the third vacuum transfer chamber 113. This vacuum transfer robot 108 loads the wafer on its arm to carry the wafer in and take it out between either wafer tables disposed respectively in the vacuum processing chambers 103 and the first lock chamber 105 or the vacuum transfer immediate chambers 112 and 112′ in the first vacuum transfer chamber 104. A passage is provided among the transfer chambers including the vacuum processing chamber 103, the first lock chamber 105 and second lock chamber 111, the first vacuum transfer intermediate chamber 112 and second vacuum transfer intermediate chamber 112′, the first vacuum transfer chamber 104 and second vacuum transfer chamber 110 and third vacuum transfer chamber 113, to communicate with each other through the valve 120 which can close and open the passages in airtight.

In this embodiment, the wafer loaded on a wafer support portion formed on an arm end portion of the atmospheric transfer robot 109 is attached to and held on the wafer support portion by an attaching device disposed on a wafer contacting surface of the wafer support portion, therefore, a wafer positional deviation caused by an arm operation can be inhibited on the wafer support portion. Particularly, it is configured that the wafer is attached on the contacting surface by a suction of an ambient gas from openings disposed in plural on the contacting surface of the wafer support portion to lower the pressure.

In contrast, convex portions such as bosses or pins, which are contacted to the wafer to inhibit the positional deviation, are disposed on the wafer support portion of the arm end portion on which the vacuum transfer robot 109 loads the wafer, instead that the attaching is not performed by the suction. Therefore, the positional deviation of the wafer caused by the arm operation is inhibited. An arm operating speed or a ratio (acceleration) of an arm operating speed variation is inhibited for a purpose of inhibiting the positional deviation. As a result, the vacuum transfer robot 108 takes a lot of time to transfer the wafer for an arbitrary distance, therefore, a transfer efficiency becomes low in the vacuum side block 102, compared with the atmospheric side block 101.

Hereinafter, in this embodiment, an example of improving the process efficiency by reducing a transfer time period during which the sample is transferred on a transfer passage through the vacuum transfer chamber, intermediate chamber and vacuum processing chamber which configure the block, will be described below, in a condition where the transfer time period in the vacuum side block 102 is long compared with that in the atmospheric side block 101. Further, the processing time period for the wafer in the vacuum processing chambers 103 is equal to or less than the transfer time period, and the transfer time period is effected largely on the processing number of wafers per unit time of the entire vacuum processing apparatus 100, particularly, effected dominantly.

Next, the following description will be concerned with an operation of performing the process for the wafer in the above-mentioned vacuum processing apparatus 100.

The plurality of wafers stored in the cassette loaded on either cassette table 107 are started to process by either receiving a command from a control device (not shown) connected with the vacuum processing apparatus 100 by a communication unit, or receiving the command from the control device etc. on a manufacturing line on which the vacuum processing apparatus 100 is installed, for adjusting the operation of vacuum processing apparatus 100. The atmospheric transfer robot 109 received the command from the control device takes out a specific wafer from the cassette to be transferred to either a predetermined first lock chamber 105 or second lock chamber 111.

For example, the first lock chamber 105 to which the wafer is transferred and stored therein is depressurized down to a predetermined pressure by closing valve 120. Thereafter, in the first lock chamber 105, the valve 120 located at the side faced to the first vacuum transfer chamber 104 is open to communicate with the first lock chamber 105 and the first vacuum transfer chamber 104.

The arm of vacuum transfer robot 108 extends inside the first lock chamber 105 to transfer the wafer in the first lock chamber 105 to the wafer support portion formed on the arm end portion and take out the wafer to inside the first vacuum transfer chamber 104. Further, the vacuum transfer robot 108 carries the wafer loaded on the arm in either the vacuum processing chamber 103 or first vacuum transfer intermediate chamber 112 coupled to the first vacuum transfer chamber 104 along with a predetermined transfer passage indicated previously by the control device, when the wafer is taken out from the cassette. For example, the wafer transferred to the first vacuum transfer intermediate chamber 112 is then taken out to the second vacuum transfer chamber 110 from the second vacuum transfer intermediate chamber 112′ by the vacuum transfer robot 108 provided in the second vacuum transfer chamber 110 to then carry the wafer in either vacuum processing chamber 103 as a destination of the above-mentioned predetermined transfer passage.

In contrast, when the wafer is transferred to and stored in the second lock chamber 111, the valve 120 located at the side faced to the third vacuum transfer chamber 113 is open to communicate with the transfer chambers of the second lock chamber 111 and third vacuum transfer chamber 113, after the valve 120 is closed to depressurize, as similarly described above. The arm of vacuum transfer robot 108 extends inside the second lock chamber 111 to take out and carry the wafer inside second lock chamber 111 in the third vacuum transfer chamber 113. Further, the vacuum transfer robot 108 carries the wafer loaded on the arm thereof in the vacuum processing chamber 103 coupled to the third vacuum transfer chamber 113 along with a predetermined passage indicated, when the wafer is taken out from the cassette.

In this embodiment, the valve 120 opens and closes exclusively. That is, the wafer transferred to the vacuum transfer intermediate chamber 112 is encased in the vacuum transfer intermediate chamber 112 by closing the valve 120 which opens and closes between the vacuum transfer intermediate chamber 112 and first vacuum transfer chamber 104. Thereafter, the valve 120, for opening and closing the passage connected between the vacuum transfer intermediate chamber 112 and second vacuum transfer chamber 110, is open to extend the arm of vacuum transfer robot 108 provided in the second vacuum transfer chamber 110 and transfer the wafer to inside the second vacuum transfer chamber 110. The vacuum transfer robot 108 then transfers the wafer loaded on the arm thereof to either one predetermined vacuum processing chamber 103 when the wafer is taken out from the cassette.

After transferring the wafer to the one vacuum processing chamber 103, the valve 120, for opening and closing the passage connected between the one vacuum processing chamber 103 and the first vacuum transfer chamber 104, is closed to seal the vacuum processing chamber 103. Thereafter, the process gas is introduced into that vacuum processing chamber 103 to adjust the pressure suitable to the process in the vacuum processing chamber. The electric field or magnetic field is then supplied to that vacuum processing chamber to therefore excite the process gas, generate plasma in this vacuum processing chamber, and process the wafer.

The valve 120, for opening and closing the passage connected between the one vacuum processing chamber 103 in which the wafer is processed and vacuum transfer chamber, is open by receiving the command from the control device in a condition where the other valve 120, which can opens and closes a space coupled and communicated with the vacuum transfer chamber, is closed. For example, before opening the valve 120 for distinguishing between the one vacuum processing chamber 103 and the vacuum transfer chamber coupled thereto, the control device indicates a confirmation operation for the opening or closing of the valve 120 for opening and closing a gate (the wafer passes through inside) disposed on other three side walls of the vacuum processing chamber. The control device then instructs to open the valve 120 which seals the one vacuum processing chamber 103 after the confirmation operation.

The valve 120, located on the passage between the other vacuum processing chamber 103 and second vacuum transfer chamber 110, is closed when detecting a finish of the wafer process, and it is confirmed that the passage between the both above-mentioned chambers is sealed in airtight. Thereafter, the valve 120, for opening and closing the passage connected between the one vacuum processing chamber 103 and second vacuum transfer chamber 110, is open. The vacuum transfer robot 108 then takes the processed wafer out to inside the vacuum processing chamber, and the wafer is transferred to either first lock chamber 105 or the second lock chamber 111 on the transfer passage opposite to a direction of carrying the wafer in the vacuum processing chamber. At this time, the valve 120, for distinguishing between the first vacuum transfer chamber 104 and second vacuum transfer chamber and between the second vacuum transfer chamber and third vacuum transfer chamber 113, may be remained open when it is confirmed that the valve 120 seals in airtight between the vacuum processing chamber 103 and the above-mentioned chambers coupled similarly thereto.

The wafer is transferred to either the first lock chamber 105 or second lock chamber 111 to then close the valve 120 which opens and closes the passage for communicating with the first lock chamber 105 and first vacuum transfer chamber 104 or the second lock chamber 111 and third vacuum transfer chamber 113, seal either the first vacuum transfer chamber 104 or third vacuum transfer chamber 113, and raise the pressure inside either the first lock chamber 105 or second lock chamber 111 up to the atmospheric pressure. Thereafter, the valve 120, for distinguishing the inside of the chassis 106, is open to communicate with between the inside of either the first lock chamber 105 or second lock chamber 111 and the inside of chassis 106. The atmospheric transfer robot 109 transfers the wafer to an initial cassette from either the first lock chamber 105 or second lock chamber 111 to put it back to an initial position in the cassette.

In this embodiment, the wafer transferred from either the first lock chamber 105 or second lock chamber 111 is transferred along the passage of a shortest transfer distance selected and instructed by the control device. The wafer processed in any vacuum processing chambers 103 is also transferred along the above-mentioned same passage. That is, in FIG. 1, the wafer carried in from the first lock chamber 105 is transferred to the vacuum processing chamber 103 coupled to the first vacuum transfer chamber 104 and second vacuum transfer chamber 110.

Further, the wafer processed in the vacuum processing chamber 103 coupled to the first vacuum transfer chamber 104 and second vacuum transfer chamber 110 is transferred to the first lock chamber 105 to then be put back to the initial cassette. The wafer carried in from the second lock chamber 111 is also transferred to the vacuum processing chamber 103 coupled to the third vacuum transfer chamber 113 so that the transfer passage becomes the shortest distance. The wafer processed in the vacuum processing chamber 103 coupled to the third vacuum transfer chamber 113 is transferred to the second lock chamber 111 to then be put back to the initial cassette.

Here, assuming that the second vacuum transfer intermediate chamber 112′ is not present, it is apparent that the number of vacuum processing chambers 103 for processing the wafer to be transferred through the first vacuum transfer chamber 104 coupled to the first lock chamber 105 is greater than that of vacuum processing chambers 103 for processing the wafer to be transferred through the third vacuum transfer chamber 113 coupled to the second lock chamber 111. In this case, an operation time period of the first vacuum transfer chamber 104 coupled to the first lock chamber 105 and the vacuum transfer robot 108 provided in the first vacuum transfer chamber 104 is longer than that of the second lock chamber side, therefore, it can be said that a transfer load is weighted toward the former side. In the case of such configuration, when the transfer load of the first lock chamber 105 side is large, the wafer transfer in either the first lock chamber 105 or the first vacuum transfer 104 stands ready to transfer despite that a preparation for taking the wafer out or carrying it in is set. For this reason, a so-called waiting time period occurs to thereby deteriorate the transfer efficiency and lower the productive efficiency in the entire apparatus. Consequently, the second vacuum transfer intermediate chamber 112′, for coupling between the first and third vacuum transfer chambers 104, 113, is disposed to thereby pass the wafer through the second vacuum transfer intermediate chamber 112′, bypass and put it back to the initial cassette on the standby side. In consequence, the transfer load of the first lock chamber 105 is dispersed and reduced.

When an unprocessed wafer is transferred to any of the vacuum processing chambers 103 coupled to either the first vacuum transfer chamber 104 or the second vacuum transfer chamber 110 and the control device determines a stagnation of the transfer in the first lock chamber 105, the atmospheric transfer robot 109 receives a command from the control device to transfer the wafer to the second lock chamber 111. For example, when a space in the storage unit of the first lock chamber 105, in which the wafer can be stored, is not present, or the control device determines that it takes much more time than an allowed time since the pressure is adjusted to the atmospheric pressure for a purpose of releasing the inside to the atmosphere, the control device instructs to operate the atmospheric transfer robot 109 so that the unprocessed wafer is transferred to the second lock chamber 111. The wafer transferred to the second lock chamber 111 is transferred to the third vacuum transfer chamber 113 by the vacuum transfer robot 108 to then be transferred to the predetermined vacuum processing chamber 103 via the second vacuum transfer intermediate chamber 112′, and the wafer is processed in that vacuum processing chamber 103.

When the wafer is put back to the cassette from the vacuum processing chamber 103 coupled to the first and second vacuum transfer chambers 104, 110 and the control device determines the stagnation of the transfer in the first lock chamber 105, the processed wafer is transferred to the second lock chamber 111 via the second vacuum transfer intermediate chamber 112′ to then be put back to the initial cassette by the command from the control device.

In contrast, when the processed wafer is transferred toward the lock chamber from the vacuum processing chamber 103 coupled to the third vacuum transfer chamber 113, the wafer is transferred to the second lock chamber 111 to be put back to the initial cassette. In this embodiment, the control device adjusts such that the processed wafer is not transferred from the first lock chamber 105 via the second vacuum transfer intermediate chamber 112′ since the first lock chamber 105 has a large transfer load as described above. The wafer transfer is performed on the passage, as a bypassing passage, passing through the second vacuum transfer intermediate chamber 112′, third vacuum transfer chamber 113 and second lock chamber 11. In consequence, the weight of transfer load between the first and second lock chambers 105, 111 is dispersed, so that the productive efficiency can be improved.

Next, in this embodiment shown in FIG. 1, one vacuum processing chambers 103 of four performs a post-process for an etching-processed wafer, that is, an ashing process is performed for removing a mask from the wafer, and the other three vacuum processing chambers 103 perform the etching process. The following description will be concerned with the layout of the vacuum processing chambers 103 and an operating procedure of the wafer transfer.

In the case of the vacuum processing apparatus providing the above-mentioned vacuum processing chambers, the vacuum transfer robot 108 provided in the vacuum transfer chamber coupled to the vacuum processing chamber, in which the ashing process is performed, has a large transfer load since all of the wafers processed in the other three vacuum processing chambers, in which the etching process is performed, are transferred from these three vacuum processing chambers. For this reason, an ashing unit is coupled to the vacuum transfer chamber having a less transfer load, in this embodiment.

In FIG. 1, the vacuum processing chamber 103 coupled to the third vacuum transfer chamber 113 performs the ashing process. The three vacuum processing chambers 103 coupled to the first vacuum transfer chamber 104 and second vacuum transfer chamber 110 perform the etching process. The unprocessed wafer transferred to the vacuum processing chamber 103 in which the etching process is performed, is transferred from the first lock chamber 105. The processed wafers transferred from the three vacuum processing chambers 103 coupled to the first vacuum transfer chamber 104 and second vacuum transfer chamber 110 are transferred to the vacuum processing chamber 103 coupled to the third vacuum transfer chamber 113 via the second vacuum transfer intermediate chamber 112′ to then apply the ashing process thereto.

In contrast, the wafer subjected to the ashing process is taken out from the vacuum processing chamber 103 to be transferred to the second lock chamber 111 without passing through the second vacuum transfer intermediate chamber 112′ and put it back to the initial position of the initial cassette in the atmospheric side block 101. As mentioned above, the vacuum processing chamber 103 in which the ashing process is performed is coupled to the third vacuum transfer chamber 113, and the control device (not shown) controls to transfer the unprocessed wafer in the first lock chamber 105 and transfer the processed wafer processed by the ashing unit in the second lock chamber 111. In consequence, the transfer load for the vacuum transfer robot 108 provided in each of the vacuum transfer chambers and the first and second lock chambers 105, 111, is dispersed to thereby improve the productive efficiency.

The above-mentioned operating procedure is of a condition where the operation of vacuum processing apparatus 100 is normal. In this normal condition, the wafer is transferred on the passage of the shortest transfer distance selected and instructed by the control device. Further, when the processed wafer is transferred toward the lock chamber from the vacuum processing chamber 103 coupled to the third vacuum transfer chamber 113, this wafer is not transferred from the first lock chamber 105 via the second vacuum transfer intermediate chamber 112′.

Hereinafter, an operating procedure for the wafer transfer will be described when an abnormality occurs in the vacuum processing apparatus 100. This abnormality includes occurrences of a wafer breakage, a fault or malfunction of the transfer robot, etc. for either the first vacuum transfer chamber 104, second vacuum transfer chamber 110, third vacuum transfer chamber 113, first vacuum transfer intermediate chamber 112, second vacuum transfer intermediate chamber 112′, first lock chamber 105, or second lock chamber 111. That is, the above-mentioned condition is that it is difficult to pass the wafer through the chambers as a transfer passage.

When the control device determines that the second lock chamber 111 cannot be used for transferring the wafer by causing the abnormality, the wafer to be transferred to the third vacuum transfer chamber 113 is transferred from the first lock chamber 105 via the second vacuum transfer intermediate chamber 112′. Further, the wafer processed in the vacuum processing chamber 103 coupled to the third vacuum transfer intermediate chamber 112′ passes through the first vacuum transfer chamber 104 via the second vacuum transfer intermediate chamber 112′ to then be taken out from the first lock chamber 105 and put back to the initial position of the initial cassette. When the control device determines that the wafer cannot be transferred for a long time period since it takes a lot of time to eliminate and restore the abnormality, all of the wafers are carried in the first lock chamber 105 or taken out from it, so that the process can be continued without halting the entire apparatus, even for a time period until the second lock chamber 111 is restored.

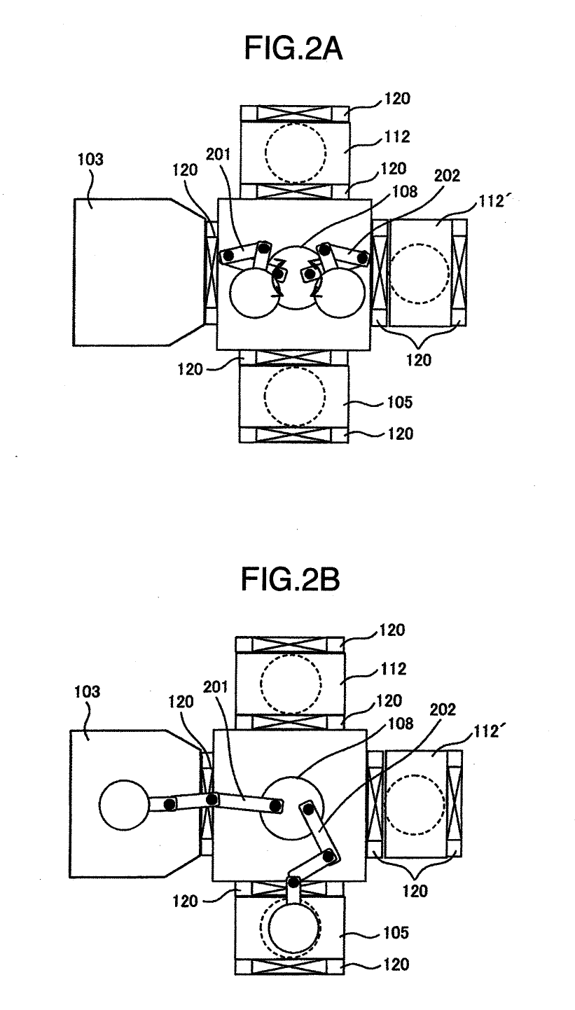

FIGS. 2A and 2B are enlarged views each showing the first vacuum transfer chamber 104 described with reference to FIG. 1. The vacuum transfer robot 108 provides a first arm 201 and a second arm 202 for transferring the wafer. In this embodiment, the number of arm is two, but a plural number of arms may be acceptable, for example, three or four.

Each of the first and second arms has a configuration capable of independently and universally moving in a rotating direction, a height direction, and an extension and contraction of the arm, regardless of moving one another. According to such configuration, the vacuum transfer robot 108 shown in FIGS. 2A and 2B can access to a plurality of transfer destinations in parallel, so that the transfer efficiency and capability of the wafer transfer can be enhanced.

FIG. 2A shows a condition where the first and second arms 201, 202 carry the wafer in the first vacuum transfer chamber 104. FIG. 2B shows a condition where the first arm 201 extends to transfer the wafer in the vacuum processing chamber 103, at the same time, the second arm 202 extends to transfer the wafer to the first lock chamber 105. Each of the transfer timings in the first and second arms 201, 202 may not be the same time completely. Each of the arms can operate the extension, contraction and rotation in parallel, for transferring the wafer to an individual destination (a wafer loaded place inside the chamber in the transfer destination).

### Modified Example

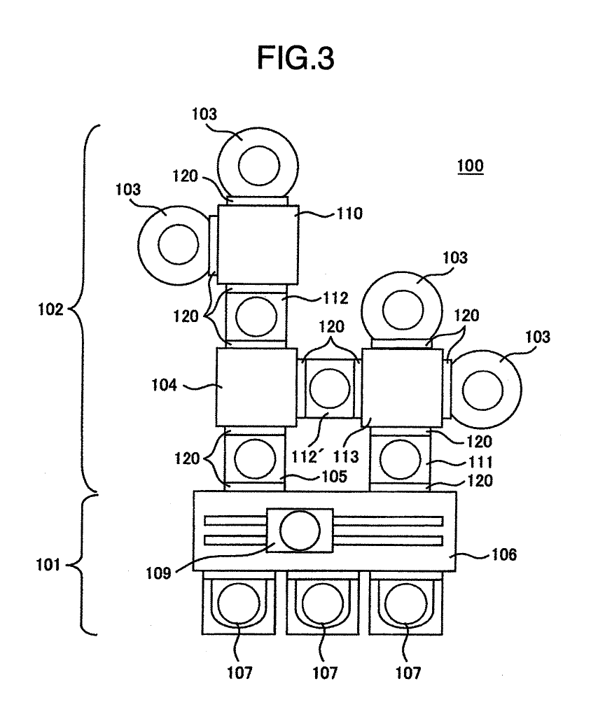

FIG. 3 shows an entire schematic configuration of the vacuum processing apparatus regarding a modified example in this embodiment of the invention. In this modified example, the first and second vacuum transfer intermediate chambers 112, 112′ alone are coupled to the first vacuum transfer chamber 104, in contrast to the embodiment shown in FIG. 1, but the vacuum processing chamber 103 is not coupled thereto. The vacuum processing chambers 103 are coupled respectively to the side walls corresponding to two sides of rectangular shape, to which the second vacuum transfer intermediate chamber 112′ and second lock chamber 111 are not coupled, in the third vacuum transfer chamber 113. In this configuration, the first vacuum transfer chamber 104 is used for transferring the wafer to the vacuum transfer intermediate chambers 112, 112′ alone.

In such configuration of the modified example, one or two vacuum processing chambers 103 among the four perform the ashing process. When the other vacuum processing chambers 103 perform the etching process, an ashing chamber is coupled to the vacuum transfer chamber nearest to the lock chamber so that the wafer finished the etching and ashing processes are returned to the initial cassette on the shortest transfer passage. Further, the vacuum processing chamber is not coupled to a vicinity of the vacuum transfer chamber, by intervening the vacuum transfer intermediate chamber, coupled to the vacuum processing chamber in which the ashing process is performed, but the vacuum transfer chamber for only transferring the wafer is coupled thereto. That is, in an example shown in FIG. 3, the vacuum processing chamber 103 coupled to the second vacuum transfer chamber 110 performs the etching process, and the ashing process is only performed in the vacuum processing chamber 103 disposed on either the side position of the vacuum processing chamber 103 coupled to the third vacuum transfer chamber 113. The vacuum processing chamber 103 is not coupled to the vacuum transfer chamber by intervening the second vacuum transfer intermediate chamber 112′, but the first vacuum transfer chamber 104 for only transferring the wafer is coupled thereto.

The wafer transferred from the first lock chamber 105 is transferred to any of the vacuum processing chambers 103, in which a predetermined etching process is performed, via either the vacuum transfer intermediate chamber 112 or 112′. In contrast, in a normal condition, the transfer passage on which the wafer is transferred and passed through the second lock chamber 111, is not selected and instructed by the control device since the wafer is transferred to the vacuum processing chamber 103 in which the etching process is performed. In this regard, when the wafer is transferred to the vacuum processing chamber 103, in which the etching process is performed, coupled to the third vacuum transfer chamber 113 in a condition where there is no wafer at all in the vacuum side block 102, the unprocessed wafer is also transferred from the second lock chamber 111 in response to the instruction from the control device.

In the vacuum processing chamber 103, in which the etching process is performed, coupled to the second vacuum transfer chamber 110, the process-finished wafer is transferred to one of the vacuum processing chambers 103, in which the ashing process is performed, coupled to the above-mentioned position by the vacuum transfer robot 108 via the second vacuum transfer intermediate chamber 112′. When the vacuum processing chamber 103, in which the etching process is performed, coupled to the third vacuum transfer chamber 113 is present, the process-finished or processed wafer is transferred to the vacuum processing chamber 103, in which the ashing process is performed, coupled to the third vacuum transfer chamber 113 by the vacuum transfer robot 108 provided in the third vacuum transfer chamber 113, without moving to the other transfer chamber. The wafer processed in the vacuum processing chamber 103, in which the ashing process is performed, is transferred to the second lock chamber 111 by the vacuum transfer robot 108 provided in the third vacuum transfer chamber 113 to be put back to the initial position in the initial cassette. The ashing process-finished wafer is not transferred to the first lock chamber 105 via the second vacuum transfer intermediate chamber 112′ and first vacuum transfer chamber 104 with the vacuum processing apparatus normal or abnormality not occurred.

In the modified example shown in FIG. 3, when the processing time period is the same for each of the vacuum processing chambers 103, there is no weight of the transfer load in the vacuum transfer chambers 104, 110, 113 and the lock chambers 105, 111 coupled to the vacuum processing chambers 103. However, the processing time period of the ashing process is normally longer than that of the etching process, and the vacuum transfer robot 108 provided in the vacuum transfer chamber 103 coupled to the vacuum processing chamber, in which the ashing process is performed, has a large transfer load since the wafers processed in each of the three vacuum processing chambers 103, in which the etching process is performed, are transferred from the three. Besides, it is also required to transfer the wafer toward the vacuum processing chambers 103 in which the ashing process is performed.

Consequently, there is no vacuum processing chamber 103 to be coupled to the first vacuum transfer chamber 104, but the first and second vacuum transfer intermediate chambers 112, 112′ are only coupled to the first vacuum transfer chamber 104. In this configuration, the control device controls to select and instruct an operation such that the second lock chamber 111 is used for only taking the processed wafer out to the atmospheric side block 101. In consequence, the transfer load in the third vacuum transfer chamber 113 is dispersed, so that the productive efficiency of the semiconductor device can be improved. In this regard, the second vacuum transfer chamber 112′ is controlled such that the wafer is transferred, in one direction alone, between the vacuum transfer chambers coupled by the instruction from the control device, in a steady state. The second vacuum transfer chamber 112′ is configured that the wafer can be transferred in a mutual direction.

The modified example shown in FIG. 3 illustrates an operating procedure when the vacuum processing apparatus 100 operates in the steady state. In the steady state, when the processed wafer is transferred toward the atmospheric side block 101 from the vacuum processing chamber 103 coupled to the third vacuum transfer chamber 113, the wafer is not taken out from the first lock chamber 105 via the second vacuum transfer intermediate chamber 112′.

In contrast, when the control device determines that the abnormality occurs in the second lock chamber 111 and the wafer cannot be transferred by using the second lock chamber 111, the processed wafer in the vacuum processing chamber 103 coupled to the third vacuum transfer chamber 113 is taken out from the first lock chamber 105 via the second vacuum transfer intermediate chamber 112′ to then be put back to the initial position of the initial cassette, by the instruction of selecting and changing the transfer passage from the control device (not shown). Further, when the control device determines that the abnormality condition continues for long time period, all of the wafers are carried in or taken out in the first lock chamber 105, so that the process can be continued for a time period until the second lock chamber 111 is restored, without halting the apparatus.

According to the above-mentioned embodiment, it is possible to provide a semiconductor manufacturing unit having high productivity per installation area.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus comprising;
an atmospheric transfer chamber disposed, on a front face side, a cassette table for mounting cassettes to store wafers and to transfer the wafers inside the cassette;
a first lock chamber and a second lock chamber coupled to a back face side of the atmospheric transfer chamber in parallel to be able to adjust an pressure to a vacuum pressure inside the cassette storing the wafers;
a first transfer chamber coupled to a rear side of the first lock chamber and having a first robot for transferring the wafer inside the first transfer chamber set to a predetermined vacuum pressure;
a second transfer chamber disposed and coupled, on the rear side of and to, the first transfer chamber and having a second robot for transferring the wafer under the vacuum;
a third transfer chamber coupled to the rear side of the second lock chamber, disposed in parallel with the first transfer chamber and having a third robot, for transferring the wafer, inside the third transfer chamber set to the vacuum;
a first relay chamber and a second relay chamber coupled to and dispose between the first transfer chamber/the second transfer chamber and the first transfer chamber/the third transfer chamber so as to seal in and providing a storage unit inside such that the wafer is transferred between either the first and the second robots or between the first and the third robot; and
a plurality of processing chambers coupled to either the first, the second or the third transfer chamber and for processing the wafer in the processing chamber, wherein
number of the processing chambers coupled to the second transfer chamber among the plurality of processing chambers is greater than that of the processing chambers coupled to either the first or the third transfer chamber, and the wafer alone processed in the processing chamber coupled to either the first or the second transfer chamber is transferred to the third robot in the second relay chamber.

2. The apparatus according to claim 1 further comprising a valve disposed to seal in between the processing chambers coupled respectively to the second and the third transfer chamber, between the relay chambers, and between the first and the second lock chamber, and
the valve disposed between the processing chambers coupled to the first, the second and the third the processing chambers opens exclusively between the first, the second and the third transfer chambers, and the respective processing chambers.

3. The apparatus according to claim 1 wherein number of the processing chambers coupled to the second transfer chamber is equal to or greater than two, and number of processing chambers coupled to the first and the second transfer chambers is equal to or less than one.

4. The apparatus according to claim 1 wherein the wafer processed in the processing chamber coupled to either the first or the second transfer chamber is taken out to an atmospheric pressure via the second relay chamber, the third transfer chamber and the second lock chamber, when another wafer stored in the first lock chamber waits.

5. The apparatus according to claim 1 wherein the wafer processed in the processing chamber coupled to either the first or the second transfer chamber is subjected to a post-process of the process inside the processing chamber coupled to the third transfer chamber.
